(19) United States
(12) Patent Application Publication
(10) Pub. No.: US 2024/0375239 A1
(43) Pub. Date: Nov. 14, 2024

(54) POLISHING PAD

(71) Applicant: KURARAY CO., LTD., Kurashiki-shi, Okayama (JP)

(72) Inventors: Yuko GOSHI, Tokyo (JP); Mitsuru KATO, Kurashiki-shi, Okayama (JP); Takashi SUGIOKA, Kurashiki-shi, Okayama (JP)

(73) Assignee: KURARAY CO., LTD., Kurashiki-shi, Okayama (JP)

(21) Appl. No.: 18/691,189

(22) PCT Filed: Sep. 22, 2022
(86) PCT No.: PCT/JP2022/035517

§ 371 Date: Mar. 12, 2024

(30) Foreign Application Priority Data
Sep. 27, 2021 (JP) 2021-156898

(51) Int. Cl. B24B 37/24; C08J 5/18; C08L 75/08

(52) U.S. Cl. CPC B24B 37/24; C08J 5/18; C08L 75/08; C08J 2367/00; C08J 2371/02; C08J 2375/08

(57) ABSTRACT

Disclosed is a polishing pad including a polishing layer that is a molded body of a polyurethane composition, wherein the polyurethane composition contains 90 to 99.9 mass % of a thermoplastic polyurethane including a non-alicyclic diisocyanate unit as an organic diisocyanate unit, and 0.1 to 10 mass % of a hygroscopic polymer, and the molded body has a hardness of 75 to 90, as measured with a type-D durometer compliant with JIS K 7215.

### TECHNICAL FIELD

The present invention relates to polishing pads, and particularly relates to a polishing pad for polishing a semiconductor wafer, a semiconductor device, a silicon wafer, a hard disk, a glass substrate, an optical product, various metals, or the like.

### BACKGROUND ART

Chemical mechanical polishing (hereinafter also referred to as “CMP”) is known as a polishing method used for mirror finishing a semiconductor wafer used as a substrate for forming an integrated circuit, and planarizing irregularities of an insulating film and a conductor film of a semiconductor device. CMP is a method in which the surface of a substrate to be polished, such as a semiconductor wafer, is polished with a polishing pad using a polishing slurry (hereinafter also simply referred to as a “slurry”) containing abrasive grains and a reaction liquid.

In CMP, polishing results change significantly depending on the properties or characteristics of the polishing layer of the polishing pad. For example, a soft polishing layer reduces scratches, which are polishing defects generated on the surface to be polished, but lowering the local planarization performance and the polishing rate for the surface to be polished. A hard polishing layer enhances the planarization performance for the surface to be polished, but increases scratches generated on the surface to be polished.

In CMP, polishing results significantly change also depending on the surface roughness of the polishing surface of the polishing layer. By controlling the surface roughness of the polishing surface to improve the slurry retention, it is possible to improve the polishing rate and the planarization performance for the surface to be polished. Also, by making the surface roughness uniform, it is possible to control the polishing uniformity. Furthermore, by enhancing the dressing performance of the polishing surface, it is also possible to reduce the process time by shortening the dressing time for providing an optimal surface roughness as a preparation of polishing, or to increase the service life of the polishing pad.

As a material of such a polishing layer having various characteristics, polyurethane is used. Also, various improvements to polyurethane have been proposed.

For example, PTL 1 below discloses a polishing pad including a polishing layer in which a polymer containing an ether bond in the main chain, such as polyoxyethylene, and water-soluble particles such as cyclodextrin are dispersed in a polymer matrix material such as a conjugated diene copolymer. Also, PTL 1 discloses that such a polishing pad provides a high polishing rate, can sufficiently suppress the generation of scratches on the surface to be polished, and can achieve high in-plane uniformity in the amount of polishing of the surface to be polished.

PTL 2 below discloses a chemical mechanical polishing pad including a polishing layer formed from a composition containing 80 parts by mass or more and 99 parts by mass or less of a thermoplastic polyurethane, and 1 parts by mass or more and 20 parts by mass or less of a polymer compound, such as polyoxyethylene, having a water absorption ratio of 3% or more and 3000% or less. PTL 2 discloses that, with such a polishing pad, the water-soluble particles in contact with a slurry are liberated to form pores, and the slurry is retained in the formed pores, thus maintaining the high planarization performance, and also reducing the generation of scratches.

PTL 3 below discloses a polishing pad including a polishing layer containing resin and first particles such as calcium carbonate particles, wherein the first particles have an average particle size D₅₀ of 1.0 to less than 5.0 μm, and the content of the first particles relative to the total amount of the polishing layer is 6.0 to 18.0 vol %, and the first particles have a Mohs hardness that is less than the Mohs hardness of a substrate to be polished. PTL 3 discloses that with such a polishing pad, the interface between the resin and the first particles becomes brittle, thus providing excellent dressing performance.

### CITATION LIST

### Patent Literatures

[PTL 1] WO 2007/089004
[PTL 2] Japanese Laid-Open Patent Publication No. 2011-151373
[PTL 3] Japanese Laid-Open Patent Publication No. 2019-155507

### SUMMARY OF INVENTION

### Technical Problem

It is difficult for the polishing pads disclosed in PTL 1 and PTL 2 to be provided with a high polishing rate, high planarization performance, scratch resistance to suppress generation of scratches, and excellent dressing performance at the same time. With the polishing pad disclosed in PTL 3, there is concern that scratches are likely to be generated due to a relatively large particle diameter of the first particles. As such, it is difficult for a polishing layer containing a polyurethane to be provided with a high polishing rate, high planarization performance, scratch resistance, and excellent dressing performance at the same time.

It is an object of the present invention to provide a polishing pad provided with a high polishing rate, high planarization performance, scratch resistance, and excellent dressing performance at the same time.

### Solution to Problem

An aspect of the present invention relates to a polishing pad including a polishing layer that is a molded body of a polyurethane composition, wherein the polyurethane composition contains 90 to 99.9 mass % of a thermoplastic polyurethane including a non-alicyclic diisocyanate unit as an organic diisocyanate unit, and 0.1 to 10 mass % of a hygroscopic polymer having a moisture absorption rate of 0.1% or more. The molded body has a D hardness of 75 to 90, as measured with a type-D durometer compliant with JIS K 7215 for a load holding time of 5 seconds. Such a polishing pad can provide a polishing pad provided with a high polishing rate, high planarization performance, scratch resistance, and excellent dressing performance at the same time.

Preferably, the thermoplastic polyurethane includes, in a total amount of the organic diisocyanate unit, 90 to 100 mol % of 4,4′-diphenylmethane diisocyanate unit serving as the non-alicyclic diisocyanate unit. In such a case, the hygroscopic polymer is likely to be dispersed in the thermoplastic polyurethane with particularly good compatibility.

Preferably, the polyurethane composition contains 99 to 99.9 mass % of the thermoplastic polyurethane, and 0.1 to 1 mass % of the hygroscopic polymer. In such a case, the polishing layer is likely to maintain a higher D hardness, and thus is likely to maintain higher planarization performance.

Examples of the hygroscopic polymer include a polyethylene oxide and a polyethylene oxide-propylene oxide block copolymer.

Preferably, the molded body has a saturated swollen state-breaking elongation of 50 to 250% when swollen to saturation with water at 50° C. In such a case, the polishing layer has a polishing surface that can be more easily roughened, while maintaining high planarization performance, and thus is likely to have excellent dressing performance.

Preferably, the molded body has a dry state-breaking elongation of 0.1 to 10% at a humidity of 48 RH % and 23° C. In such a case, the polishing layer can easily maintain high planarization performance.

Preferably, the molded body has a ratio of S₁/S₂ of 20 to 50, where S₁ represents the above-described saturated swollen state-breaking elongation and S₂ represents the above-described dry state-breaking elongation. In such a case, a polishing layer with particularly good dressing performance and planarization performance can be easily obtained.

Preferably, the molded body, in a form of a sheet having a thickness of 0.5 mm, has a laser light transmittance of 60% or more for 550-nm wavelength when swollen to saturation with water at 50° C. In such a case, a polishing layer having excellent scratch resistance and being easily adopted a detection using optical detection means for determining an end point of polishing while polishing a surface to be polished of a substrate to be polished, such as a wafer, can be easily obtained.

Preferably, the molded body has a Vickers hardness of 21 or more. In such a case, a polishing layer with particularly good planarization performance can be easily obtained.

Preferably, the molded body has a storage modulus of 0.1 to 1.0 GPa when swollen to saturation with water at 50° C. In such a case, a polishing layer that can be easily allowed to maintain higher planarization performance can be easily obtained.

Preferably, the molded body is an unfoamed molded body. In such a case, the hardness of the polishing layer is more likely to be increased, which makes it possible to more easily achieve higher planarization performance and a higher polishing rate. In addition, an abrasive grain agglomerate, which is formed as a result of the abrasive grains contained in the slurry penetrating into the pores, is less likely to be generated, so that scratches generated as a result of such an agglomerate scratching the wafer surface are less likely to be generated.

### Advantageous Effects of Invention

According to the present invention, a polishing pad provided with a high polishing rate, high planarization performance, scratch resistance, and excellent dressing performance at the same time can be provided.

### BRIEF DESCRIPTION OF DRAWINGS

FIG. 1 is an explanatory diagram for illustrating CMP using a polishing pad 10 according to an embodiment.

### DESCRIPTION OF EMBODIMENT

In the following, an embodiment of a polishing pad will be described in detail.

The polishing pad according to the present embodiment includes a polishing layer that is a molded body of a polyurethane composition. The polyurethane composition contains 90 to 99.9 mass % of a thermoplastic polyurethane including a non-alicyclic diisocyanate unit as an organic diisocyanate unit (hereinafter also referred to as a non-alicyclic thermoplastic polyurethane), and 0.1 to 10 mass % of a hygroscopic polymer. The molded body has a D hardness of 75 to 90, as measured with a type-D durometer compliant with JIS K 7215 for a load holding time of 5 seconds.

The non-alicyclic thermoplastic polyurethane is a thermoplastic polyurethane obtained by reacting a polyurethane raw material containing an organic diisocyanate, a polymer diol, and a chain extender. Also, the non-alicyclic thermoplastic polyurethane is a thermoplastic polyurethane obtained using an organic diisocyanate containing a non-alicyclic diisocyanate. The content ratio of the non-alicyclic diisocyanate unit contained in a total amount of the organic diisocyanate units contained in the non-alicyclic thermoplastic polyurethane is preferably 60 to 100 mol %, more preferably 90 to 100 mol %, particularly preferably 95 to 100 mol %, quite particularly preferably 99 to 100 mol %. When the content ratio of the non-alicyclic diisocyanate units is too low, the compatibility between the non-alicyclic thermoplastic polyurethane and the hygroscopic polymer tends to be reduced.

By using such a molded body of a polyurethane composition as a polishing layer of a polishing pad, it is possible to obtain a polishing pad including a polishing layer provided with a high polishing rate, high planarization performance, scratch resistance, and excellent dressing performance at the same time.

In such a molded body of a polyurethane composition, the dispersibility of the hygroscopic polymer contained in the molded body is increased due to an increased compatibility between the non-alicyclic thermoplastic polyurethane and the hygroscopic polymer. More specifically, a soft segment derived from the polymer diol in the non-alicyclic thermoplastic polyurethane and the hygroscopic polymer become more compatible. Then, the stretchability of the molded layer is appropriately enhanced when the polishing layer that is the molded body is moistened with a slurry. Accordingly, dressing for optimizing the surface roughness of the polishing surface can be completed in a short time.

On the other hand, a crystalline hard segment derived from the chain extender and contained in the non-alicyclic thermoplastic polyurethane has low compatibility with the hygroscopic polymer. Therefore, the crystalline hard segment is likely to be retained. As a result, the hardness of the non-alicyclic thermoplastic polyurethane is less likely to be reduced. That is, the hygroscopic polymer has high compatibility with the soft segment, and has a low compatibility with the hard segment.

Consequently, a polishing layer that is a molded body containing a thermoplastic polyurethane can be obtained, wherein the polishing layer has an increased stretchability when moistened by containing a hygroscopic polymer, and can maintain a high hardness. Such a polishing layer, due to its high hardness, namely a D hardness of 75 to 90, maintains a high polishing rate and high planarization performance, and can also maintain high dressing performance attributed to the stretchability enhancing effect of a hygroscopic polymer that is likely to be unevenly distributed in the soft segment, and the scratch resistance provided by the hydrophilicity of the hygroscopic polymer.

The non-alicyclic diisocyanate used for the production of the non-alicyclic thermoplastic polyurethane refers to a diisocyanate other than an alicyclic diisocyanate, and more specifically, refers to an aromatic diisocyanate or linear aliphatic diisocyanate having no aliphatic ring structure.

The aromatic diisocyanate is a diisocyanate compound containing an aromatic ring in the molecular structure. Specific examples thereof include 2,4′-diphenylmethane diisocyanate, 4,4′-diphenylmethane diisocyanate, 2,4-tolylene diisocyanate, 2,6-tolylene diisocyanate, m-phenylene diisocyanate, p-phenylene diisocyanate, m-xylylene diisocyanate, p-xylylene diisocyanate, 1,5-naphthylene diisocyanate, 4,4′-diisocyanatobiphenyl, 3,3′-dimethyl-4,4′-diisocyanatobiphenyl, 3,3′-dimethyl-4,4′-diisocyanatodiphenylmethane, chlorophenylene-2,4-diisocyanate, and tetramethylxylylene diisocyanate.

The linear aliphatic diisocyanate is a diisocyanate compound having a linear aliphatic skeleton having no ring structure in the molecular structure. Specific examples thereof include ethylene diisocyanate, tetramethylene diisocyanate, pentamethylene diisocyanate, hexamethylene diisocyanate, 2,2,4-trimethyl hexamethylene diisocyanate, 2,4,4-trimethyl hexamethylene diisocyanate, dodecamethylene diisocyanate, isophorone diisocyanate, lysine diisocyanate, 2,6-diisocyanatomethyl caproate, bis(2-isocyanatoethyl)fumarate, bis(2-isocyanatoethyl)carbonate, and 2-isocyanatoethyl-2,6-diisocyanatohexanoate.

The non-alicyclic thermoplastic polyurethane is obtained using, as an organic diisocyanate used as a raw material, an organic diisocyanate containing, for example, 60 mol % or more, preferably 90 mol % or more, more preferably 95 mol % or more, particularly preferably 99 mol % or more, quite particularly preferably 100 mol % of a non-alicyclic diisocyanate.

The non-alicyclic diisocyanates may be used alone or in combination of two or more thereof. Among these, it is particularly preferable to use an organic diisocyanate including preferably an aromatic diisocyanate, more preferably 4,4′-diphenylmethane diisocyanate, 2,4-tolylene diisocyanate, 2,6-tolylene diisocyanate, and isophorone diisocyanate, particularly preferably 100 mol % of 4,4′-diphenylmethane diisocyanate, from the viewpoint of obtaining a polishing pad having particularly good planarization performance.

Note that the non-alicyclic diisocyanate may be used in combination with an alicyclic diisocyanate as long as the effects of the present invention are not impaired. The alicyclic diisocyanate is a diisocyanate compound containing an aliphatic ring structure. Specific examples thereof include isopropylidene bis(4-cyclohexyl isocyanate), cyclohexylmethane diisocyanate, methylcyclohexane diisocyanate, 4,4′-dicyclohexylmethane diisocyanate, cyclohexylene diisocyanate, methylcyclohexylene diisocyanate, and bis(2-isocyanatoethyl)-4-cyclohexylene. When the content ratio of the alicyclic diisocyanate is too high, the compatibility with the hygroscopic polymer is reduced, and the planarization performance also tend to be reduced.

The polymer diol is a diol having a number-average molecular weight of 300 or more, and examples thereof include polyether diol, polyester diol, polycarbonate diol, and a polymer diol including any combination thereof.

Specific examples of the polyether diol include poly(ethylene glycol), poly(propylene glycol), poly(tetramethylene glycol), poly(methyl tetramethylene glycol), poly(oxypropylene glycol), and a glycerin-based polyalkylene ether glycol. These may be used alone or in combination of two or more thereof. Among these, poly(ethylene glycol) and poly(tetramethylene glycol) are preferable because of their particularly good compatibility with the hard segment of the non-alicyclic thermoplastic polyurethane.

A polyester diol refers to a polymer diol having an ester structure in the main chain, produced by a direct esterification reaction or transesterification reaction between dicarboxylic acid or an ester-forming derivative thereof (e.g., an ester, anhydride, etc.) and a low-molecular weight diol.

Specific examples of the dicarboxylic acid include C2-C12 aliphatic dicarboxylic acids such as oxalic acid, succinic acid, glutaric acid, adipic acid, pimelic acid, suberic acid, azelaic acid, sebacic acid, dodecanedicarboxylic acid, 2-methyl succinic acid, 2-methyl adipic acid, 3-methyl adipic acid, 3-methyl pentanedioic acid, 2-methyloctanedioic acid, 3,8-dimethyldecanedioic acid, and 3,7-dimethyldecanedioic acid; C14-C48 dimerized aliphatic dicarboxylic acids (dimer acids) obtained by dimerization of unsaturated fatty acids obtained by fractional distillation of triglycerides, as well as hydrogenated products (hydrogenated dimer acid) from these C14-C48 dimerized aliphatic dicarboxylic acids; alicyclic dicarboxylic acids such as 1,4-cyclohexane dicarboxylic acid; and aromatic dicarboxylic acids such as terephthalic acid, isophthalic acid, and ortho-phthalic acid. These may be used alone or in combination of two or more thereof.

Specific examples of the low-molecular weight diol include aliphatic diols such as ethylene glycol, 1,3-propanediol, 1,2-propane diol, 2-methyl-1,3-propanediol, 1,4-butanediol, neopentyl glycol, 1,5-pentanediol, 3-methyl-1,5-pentanediol, 1,6-hexanediol, 1,7-heptanediol, 1,8-octanediol, 2-methyl-1,8-octanediol, 1,9-nonanediol, and 1,10-decanediol; and alicyclic diols such as cyclohexane dimethanol (e.g., 1,4-cyclohexane dimethanol) and cyclohexanediol (e.g., 1,4-cyclohexanediol). These may be used alone or in combination of two or more thereof. Among these, low-molecular weight diols having 3 to 12 carbon atoms are preferable, and low-molecular weight diols having 4 to 9 carbon atoms are more preferable.

A polycarbonate diol is obtained by reaction of a low-molecular weight diol and a carbonate compound such as dialkyl carbonate, alkylene carbonate, and diaryl carbonate. Examples of the low-molecular weight diol include the same low-molecular weight diols as those described above. Specific examples of the dialkyl carbonate include dimethyl carbonate and diethyl carbonate. Specific examples of the alkylene carbonate include ethylene carbonate. Specific examples of the diaryl carbonate include diphenyl carbonate.

Among the polymer diols, polyether diols such as poly(ethylene glycol) and poly(tetramethylene glycol), and polyester diols such as poly(nonamethylene adipate)diol, poly(2-methyl-1,8-octamethylene adipate)diol, poly(2-methyl-1,8-octamethylene-co-nonamethylene adipate)diol, and poly(methylpentane adipate)diol are preferable, and polyester diols including a low-molecular weight diol unit having 6 to 12 carbon atoms are particularly preferable because of their particularly good compatibility with the hard segment derived from the chain extender unit of the non-alicyclic thermoplastic polyurethane.

The number-average molecular weight of the polymer diol is 300 or more, preferably from more than 300 to 2,000, more preferably 350 to 2000, particularly preferably 500 to 1,500, quite particularly preferably 600 to 1,000, because high compatibility with the hard segment in the non-alicyclic thermoplastic polyurethane can be maintained, which makes it possible to obtain a polishing layer that can easily suppress the generation of scratches on the surface to be polished. Note that the number-average molecular weight of the polymer diol refers to a number-average molecular weight calculated based on the hydroxyl value measured in accordance with JIS K 1557.

As the chain extender, chain extenders conventionally used for the production of polyurethane, which are compounds including, in the molecule, two or more active hydrogen atoms capable of reacting with an isocyanate group, and having a molecular weight of 300 or less, can be used.

Specific examples of the chain extender include diols such as ethylene glycol, diethylene glycol, propylene glycol, 2,2-diethyl-1,3-propanediol, 1,2-, 1,3-, 2,3- or 1,4-butanediol, 1,5-pentanediol, neopentyl glycol, 1,6-hexanediol, 3-methyl-1,5-pentanediol, 1,4-bis(β-hydroxyethoxy)benzene, 1,4-cyclohexanediol, bis-(β-hydroxyethyl)terephthalate, 1,9-nonanediol, and m- or p-xylylene glycol; and diamines such as ethylenediamine, trimethylene diamine, tetramethylene diamine, hexamethylene diamine, heptamethylene diamine, octamethylene diamine, nonamethylene diamine, decamethylene diamine, undecamethylene diamine, dodecamethylene diamine, 2,2,4-trimethylhexamethylenediamine, 2,4,4-trimethylhexamethylenediamine, 3-methylpentamethylenediamine, 1,2-cyclohexanediamine, 1,3-cyclohexanediamine, 1,4-cyclohexanediamine, 1,2-diaminopropane, 1,3-diaminopropane, hydrazine, xylylene diamine, isophoronediamine, piperazine, o-, m- or p-phenylenediamine, tolylenediamine, xylenediamine, adipic acid dihydrazide, isophthalic acid dihydrazide, 4,4′-diaminodiphenylmethane, 4,4′-diaminodiphenylether, 4,4′-bis(4-aminophenoxy)biphenyl, 4,4′-bis(3-aminophenoxy)biphenyl, 1,4′-bis(4-aminophenoxy)benzene, 1,3′-bis(4-aminophenoxy)benzene, 1,3-bis(3-aminophenoxy)benzene, 3,4′-diaminodiphenylether, 4,4′-diaminodiphenylsulfone, 3,4-diaminodiphenylsulfone, 3,3′-diaminodiphenylsulfone, 4,4′-methylene-bis(2-chloroaniline), 3,3′-dimethyl-4,4′-diaminobiphenyl, 4,4′-diaminodiphenylsulfide, 2,6′-diaminotoluene, 2,4-diaminochlorobenzene, 1,2-diaminoanthraquinone, 1,4-diaminoanthraquinone, 3,3′-diaminobenzophenone, 3,4-diaminobenzophenone, 4,4′-diaminobenzophenone, 4,4′-diaminobibenzyl, R(+)-2,2′-diamino-1,1′-binaphthalene, S(+)-2,2′-diamino-1,1′-binaphthalene, 1,n-bis(4-aminophenoxy) C3-10 alkane (n is 3 to 10) (e.g., 1,3-bis(4-aminophenoxy) C3-10 alkane, 1,4-bis(4-aminophenoxy) C3-10 alkane, 1,5-bis(4-aminophenoxy) C3-10 alkane, etc.)) 1,2-bis[2-(4-aminophenoxy)ethoxy]ethane, 9,9-bis(4-aminophenyl)fluorene, and 4,4′-diaminobenzanilide. These may be used alone or in combination of two or more thereof.

Among the chain extenders, 1,3-propanediol, 1,4-butanediol, neopentyl glycol, 1,5-pentanediol, 1,6-hexanediol, 1,9-nonanediol, and 1,4-cyclohexane dimethanol are particularly preferable because of their good compatibility with the soft segment derived from the polymer diol unit.

The molecular weight of the chain extender is 300 or less, and is particularly preferably 60 to 300, from the viewpoint of good compatibility between the soft segment and the hard segment.

As described above, the non-alicyclic thermoplastic polyurethane is obtained by reacting a polyurethane raw material containing an organic diisocyanate containing a non-alicyclic diisocyanate, a polymer diol, and a chain extender. For the production of the non-alicyclic thermoplastic polyurethane, any known polyurethane synthesis method using a prepolymer method or one-shot method involving a urethanation reaction can be used without any particular limitation. Among these, a method in which the polyurethane raw material is subjected to melt-polymerization substantially in the absence of a solvent is preferable, and a method in which the polyurethane raw material is subjected to continuous melt-polymerization using a multi-screw extruder is particularly preferable because of the excellent continuous productivity.

The mixing ratio of the polymer diol, the organic diisocyanate, and the chain extender in the polyurethane raw material can be adjusted as appropriate. However, from the viewpoint of the excellent mechanical strength and abrasion resistance of the resulting polishing layer, it is preferable to mix the components such that the isocyanate group contained in the organic diisocyanate is in an amount of preferably 0.95 to 1.30 moles, more preferably 0.96 to 1.10 moles, particularly preferably 0.97 to 1.05 moles, per mole of the active hydrogen atoms contained in the polymer diol and the chain extender.

The mass ratio of the polymer diol, the organic diisocyanate, and the chain extender in the polyurethane raw material (mass of polymer diol:total mass of organic diisocyanate and chain extender) is preferably 10:90 to 50:50, more preferably 15:85 to 40:60, particularly preferably 20:80 to 30:70.

The content ratio of nitrogen atoms derived from the isocyanate group in the non-alicyclic thermoplastic polyurethane is preferably 4.5 to 7.5 mass %, more preferably 5.0 to 7.3 mass %, particularly preferably 5.3 to 7.0 mass %, because a polishing layer having, due to its moderate hardness, particularly high planarization performance and polishing efficiency for a surface to be polished, and in which the generation of scratches is particularly suppressed can be obtained.

Preferred among non-alicyclic thermoplastic polyurethanes obtained in this manner is a thermoplastic polyurethane obtained by reacting a polymer diol such as poly(ethylene glycol), poly(tetramethylene glycol), poly(nonamethylene adipate)diol, poly(2-methyl-1,8-octamethylene adipate)diol, poly(2-methyl-1,8-octamethylene-co-nonamethylene adipate)diol, and poly(methylpentane adipate)diol; an organic diisocyanate such as 4,4′-diphenylmethane diisocyanate, 2,4-tolylene diisocyanate, and 2,6-tolylene diisocyanate; and at least one chain extender selected from the group consisting of 1,3-propanediol, 1,4-butanediol, neopentyl glycol, 1,5-pentanediol, 1,6-hexanediol, and 1,4-cyclohexane dimethanol, etc., because such a thermoplastic polyurethane has excellent optical transmission, so that means for optically detecting the polishing amount can be easily adopted in CMP.

The weight-average molecular weight of the non-alicyclic thermoplastic polyurethane is preferably 80,000 to 200,000, more preferably 120,000 to 180,000, from the viewpoint of the particularly good compatibility with the hygroscopic polymer. Note that the weight-average molecular weight is a weight-average molecular weight in terms of polystyrene measured by gel permeation chromatography.

Note that the polyurethane composition according to the present embodiment may contain a thermoplastic polyurethane that does not contain a non-alicyclic diisocyanate in the organic diisocyanate unit (hereinafter also referred to as an alicyclic thermoplastic polyurethane) as long as the effects of the present invention are not impaired. In the case of containing an alicyclic thermoplastic polyurethane, the content ratio of the alicyclic thermoplastic polyurethane in the polyurethane composition is preferably 0 to 9.9 mass %, more preferably 0 to 5 mass %.

The polyurethane composition according to the present embodiment contains a hygroscopic polymer. The hygroscopic polymer acts to particularly enhance the dressing performance of a polishing layer that is a molded body of a polyurethane composition.

A hygroscopic polymer refers to a polymer having a moisture absorption rate of 0.1% or more, and is defined as a polymer having a moisture absorption rate of preferably 0.1 to 5.0%, more preferably 0.1 to 3.0%, particularly preferably 0.5 to 3.0%, quite particularly preferably 0.7 to 2.5%. Note that the moisture absorption rate of a hygroscopic polymer is calculated as follows. On a plate made of glass, 5.0 g of particles of a hygroscopic polymer to be mixed are thinly spread, then dried by being allowed to stand in a hot-air dryer at 50° C. for 48 hours, and subsequently allowed to stand under constant temperature and humidity conditions of 23° C. and 50% RH for 24 hours. Then, the moisture absorption rate is calculated based on the change in mass. Specifically, a weight (W1) immediately before the treatment under constant temperature and humidity conditions of 23° C. and 50% RH, and a weight (W2) after the treatment under the under constant temperature and humidity conditions of 23° C. and 50% RH are measured, and the moisture absorption rate is determined from the following mathematical expression:

Moisture absorption rate (%)={(W2−W1)/W1}×100

Examples of such a hygroscopic polymer include polymers including a polyalkylene oxide structure such as a polymethylene oxide structure, a polyethylene oxide structure, a polypropylene oxide structure, a polytetramethylene oxide structure, and a polybutylene oxide structure.

Specific examples of such a hygroscopic polymer include ether-based hygroscopic polymers such as polyethylene oxide (PEO), polypropylene oxide (PPO), a PEO-PPO block copolymer, a polyester-based thermoplastic elastomer (TPEE), polymethylene oxide alkyl ether, polyethylene oxide alkyl ether, polyethylene oxide alkylphenyl ether, polyethylene oxide sterol ether, a polyethylene oxide lanolin derivative, a polyethylene oxide-polypropylene oxide copolymer, and polyethylene oxide-polypropylene alkyl ether; and ether ester-based hygroscopic polymers such as polyethylene oxide glycerin fatty acid ester, polyethylene oxide sorbitan fatty acid ester, polyethylene oxide sorbitol fatty acid ester, polyethylene oxide fatty acid alkanol amide sulfate, polyethylene glycol fatty acid ester, and ethylene glycol fatty acid ester.

The weight-average molecular weight of the hygroscopic polymer is preferably 5,000 to 10,000,000, more preferably 10,000 to 10,000,000, even more preferably 30,000 to 7,000,000, particularly preferably 70,000 to 4,000,000, from the viewpoint of the particularly good compatibility with the non-alicyclic thermoplastic polyurethane. Note that the weight-average molecular weight of the hygroscopic polymer is a value measured by gel permeation chromatography (in terms of polystyrene).

The hygroscopic polymer enhances the dressing performance of the polishing layer. The hygroscopic polymer has high compatibility with the soft segment of the non-alicyclic thermoplastic polyurethane. On the other hand, the hygroscopic polymer has low compatibility with the hard segment of the non-alicyclic thermoplastic polyurethane.

The content ratio of the non-alicyclic thermoplastic polyurethane in the polyurethane composition is 90 to 99.9 mass %, preferably 95 to 99.9 mass %, more preferably 99 to 99.9 mass %. When the content ratio of the non-alicyclic thermoplastic polyurethane is less than 90 mass %, the planarization performance and the polishing rate are reduced. When the aforementioned content ratio is greater than 99.9 mass %, the content ratio of the hygroscopic polymer becomes less than 0.1 mass %, which results in a reduction in the effect of enhancing the dressing performance and the effect of reducing the generation of scratches.

The content ratio of the hygroscopic polymer in the polyurethane composition is 0.1 to 10 mass %, preferably 0.1 to 5 mass %, more preferably 0.1 to 1 mass %. When the content ratio of the hygroscopic polymer is less than 0.1 mass %, the effect of enhancing the dressing performance and the effect of reducing the generation of scratches are reduced. When the content ratio of the hygroscopic polymer is greater than 10 mass %, the breaking elongation when swollen with water is excessively increased, so that the dressing performance tends to be degraded.

The polyurethane composition according to the present embodiment may contain, as necessary, additives such as a crosslinking agent, a filler, a crosslinking accelerator, a crosslinking auxiliary, a softening agent, a tackifier, an aging inhibitor, a processing auxiliary, an adhesion-imparting agent, an inorganic filler, an organic filler, a crystal nucleating agent, a heat stabilizer, a weathering stabilizer, an antistatic agent, a colorant, a lubricant, a flame retardant, a flame retardant accelerator (e.g., antimony oxide), a blooming inhibitor, a release agent, a thickener, an antioxidant, and a conductive agent, as long as the effects of the present invention are not impaired. Note that the molded body of the polyurethane composition according to the present embodiment is preferably an unfoamed molded body, and therefore preferably contains no foaming agent.

The polyurethane composition is prepared by melt-kneading a blend containing the non-alicyclic thermoplastic polyurethane, the hygroscopic polymer, and other thermoplastic polyurethanes and additives that are mixed as necessary. More specifically, the polyurethane composition is prepared by melt-kneading, using a single- or multi-screw extruder, a roll, a Banbury mixer, a Labo Plastomill (registered trademark), a Brabender, or the like, a blend prepared by uniformly mixing, using a Henschel mixer, a ribbon blender, a V-type blender, a tumbler, or the like, the non-alicyclic thermoplastic polyurethane, the hygroscopic polymer, and other thermoplastic polyurethanes and additives that are mixed as necessary. The temperature and kneading time during melt-kneading are selected as appropriate according to the type, ratio of the non-alicyclic thermoplastic polyurethane, the type of the melt-kneading machine, etc. For example, the melting temperature is preferably in the range of 200 to 300° C.

The polyurethane composition is molded into a molded body for polishing layers. The molding method is not particularly limited, and examples thereof include methods in which a molten mixture extrusion-molded using a T-die or injection-molded. In particular, extrusion molding using a T-die is preferable because a molded body for polishing layers having a uniform thickness can be easily obtained. In this manner, a molded body for polishing layers is obtained.

It is preferable that a molded body for polishing layers is an unfoamed molded body in that an increased hardness results in particularly good planarization performance, that the surface without pores prevent accumulation of polishing debris and thus reduces the generation of scratches, and that the polishing layer has a low ware rate and thus can be used for a long period of time.

The molded body has a durometer D hardness of 75 to 90, as measured with a type-D durometer compliant with JIS K 7215 for a load holding time of 5 seconds. When the molded body has such a high hardness, high planarization performance and a high polishing rate are maintained. When the durometer D hardness is less than 75, the polishing layer becomes soft, resulting in a reduction in the polishing efficiency. On the other hand, when the durometer D hardness is 91 or more, scratches are likely to be generated.

It is preferable that the molded body has a Vickers hardness of 21 or more, because a polishing layer exhibiting particularly good planarization performance can be obtained. Here, the Vickers hardness is defined as a hardness measured by a Vickers indenter compliant with JIS Z 2244. The upper limit of such a Vickers hardness is not particularly limited, and is, for example, 90.

When the stretchability of the molded body, in particular, the stretchability when the molded body has absorbed a slurry, is high, the polishing surface of the polishing layer can be easily roughened, so that the dressing performance is enhanced. Therefore, the saturated swollen state-breaking elongation S₁ of the molded body when swollen to saturation with water at 50° C. is preferably 50 to 250%, more preferably 50 to 230%, particularly preferably 50 to 200%. The dry state-breaking elongation S₂ of the molded body at a humidity of 48 RH % and 23° C. is preferably 0.1 to 10%, more preferably 1 to 10%, particularly preferably 2 to 9%. The ratio of S₁/S₂ between the saturated swollen state-breaking elongation S₁ and the dry state-breaking elongation S₂ is preferably 20 to 50, because a polishing layer having particularly good dressing performance and planarization performance can be obtained.

It is preferable that the molded body, in the form of a sheet having a thickness of 0.5 mm, has a laser light transmittance of 60% or more for 550 nm laser wavelength when swollen to saturation with water at 50° C., because the amount of generation of scratches can be more easily reduced, and a detection using optical means for determining an end point of polishing while polishing a surface to be polished of a substrate to be polished such as a wafer can be more easily adopted.

The molded body has a storage modulus of preferably 0.1 to 1.0 GPa, more preferably 0.2 to 0.9 GPa, particularly preferably 0.3 to 0.8 GPa, when swollen to saturation with water at 50° C., because higher planarization performance can be easily maintained. If the storage modulus when swollen to saturation with water at 50° C. is too low, the polishing layer becomes soft, so that the planarization performance tends to be degraded, and the polishing rate tends to be reduced. If the storage modulus when swollen to saturation with water at 50° C. is too high, scratches tend to be generated.

The contact angle with water of the molded body is preferably 80 degrees or less, more preferably 60 degrees or less, particularly preferably 50 degrees or less. When the contact angle is too high, scratches tend to be generated.

Next, a description will be given of a polishing pad including, as a polishing layer, such a molded body for polishing layers. The polishing pad according to the present embodiment includes a polishing layer formed by cutting out a piece, such as a circular piece, from a molded body for polishing layers.

The polishing layer is produced by adjusting the dimensions, shape, thickness, and the like of the molded body for polishing layers obtained in the above-described manner by cutting, slicing, buffing, punching, and the like. In order to allow a slurry to be uniformly and sufficiently supplied onto the polishing surface of the polishing layer, it is preferable that the recesses such as grooves or holes are formed in the polishing surface. Such recesses are also useful to discharge polishing debris that may cause the generation of scratches, and to prevent damage to a wafer as a result of absorption of the polishing pad.

The thickness of the polishing layer is not particularly limited, and is, for example, preferably 0.8 to 3.0 mm, more preferably 1.0 to 2.5 mm, particularly preferably 1.2 to 2.0 mm.

The polishing pad is a polishing pad including a polishing layer that is the above-described molded body of a polyurethane composition, and may be either a monolayer polishing pad composed only of the polishing layer, or a multilayer polishing pad in which a cushioning layer or the like is further stacked on a back surface of the polishing layer. It is preferable that the cushioning layer is a layer having a hardness lower than the hardness of the polishing layer because this makes it possible to improve the polishing uniformity while maintaining the dressing performance.

Specific examples of materials that can be used as the cushioning layer include composites (e.g., “Suba 400” (manufactured by Nitta Haas Incorporated)) obtained by impregnating a non-woven fabric with a polyurethane; rubbers such as a natural rubber, a nitrile rubber, a polybutadiene rubber, and a silicone rubber; thermoplastic elastomers such as a polyester-based thermoplastic elastomer, a polyamide-based thermoplastic elastomer, and a fluorine-based thermoplastic elastomer; foamed plastics; and polyurethanes. Among these, polyurethanes having a foamed structure are particularly preferable in that the flexibility desirable for the cushioning layer can be easily achieved.

The polishing pad according to the present embodiment described above can be preferably used for CMP. Next, an embodiment of CMP for which the polishing pad 10 of the present embodiment is used will be described.

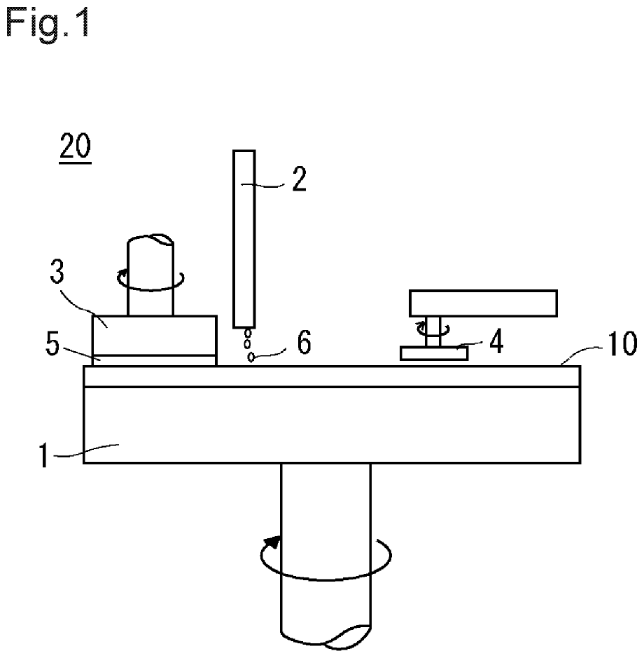

In CMP, a CMP apparatus 20 including a circular platen 1, a slurry supply nozzle 2 for supplying a slurry 6, a carrier 3, and a dresser 4 as shown in FIG. 1 is used, for example. A polishing pad 10 is attached to the surface of the platen 1 by means of a double-sided pressure-sensitive adhesive sheet or the like. In addition, the carrier 3 supports a substrate 5 to be polished.

In the CMP apparatus 20, the platen 1 is rotated by a motor (not shown), for example, in the direction indicated by the arrows. The carrier 3 is rotated by a motor (not shown), for example, in the direction indicated by the arrows, while bringing a surface to be polished of the substrate 5 to be polished into pressure contact with the polishing surface of the polishing pad 10. The dresser 4 is rotated, for example, in the direction indicated by the arrows.

When a polishing pad is used, dressing for forming a roughness suitable for polishing by finely roughening the polishing surface of the polishing pad is performed prior to, or while polishing the substrate to be polished. Specifically, while pouring water onto the surface of the polishing pad 10 that is fixed to the platen 1 and is being rotated, the dresser 4 for CMP is pressed against the surface of the polishing pad 10 so as to condition the surface. As the dresser, it is possible to use, for example, a diamond dresser in which diamond particles are fixed onto the surface of a carrier by electrodeposition of nickel, or the like.

As for the type of the dresser, dressers with a diamond grit of #60 to 200 are preferable, and the dresser may be selected as appropriate according to the resin composition of the polishing layer and the polishing conditions. The dresser load may vary depending on the diameter of the dresser, and is preferably about 5 to 50 N for a diameter of 150 mm or less, preferably about 10 to 250 N for a diameter of 150 to 250 mm, and preferably about 50 to 300 N for a diameter of 250 mm or more. The rotational speed of each of the dresser and the platen is preferably 10 to 200 rpm. In order to prevent synchronization of rotations, it is preferable that the numbers of rotation of the dresser and the platen are different.

In the case of a polishing pad including a polishing layer having a high hardness, the polishing surface of the polishing layer is less likely to be sufficiently roughened. In addition, it may require time to form a roughness suitable for polishing. It may also require time for break-in for roughening the surface of an unused polishing pad. With the polishing pad according to the present embodiment, the polishing surface can be sufficiently roughened, and the dressing time can also be reduced.

In the polishing pad according to the present embodiment, it is preferable to form a rough surface having an arithmetic surface roughness Ra of 4.0 to 8.0 μm, more preferably 4.2 to 8.0 μm. When the arithmetic surface roughness is low and the dressing is insufficient, the polishing surface is less likely to retain the slurry, so that the polishing rate tends to be reduced. When the arithmetic surface roughness Ra is too high, there is concern that the surface layer of the polishing pad comes into solid contact with the surface to be polished of the substrate to be polished, so that scratches are likely to be generated.

After completion of dressing, the polishing of the surface to be polished of the base material to be polished is started. In polishing, the slurry 6 is supplied from the slurry supply nozzle 2 onto the surface of the rotating polishing pad. The slurry contains, for example, a liquid medium such as water or oil; an abrasive such as silica, alumina, cerium oxide, zirconium oxide, or silicon carbide; a base; an acid; a surfactant; an oxidizing agent; a reducing agent; and a chelating agent. When performing CMP, a lubricating oil, a coolant, and the like may be used in combination with the slurry, as necessary. Then, the substrate to be polished that is fixed to the carrier and is being rotated is pressed against the polishing pad on which the slurry is evenly spread on the polishing surface. Then, the polishing treatment is continued until a predetermined flatness or polishing amount is achieved. Adjustment of the pressing force applied during polishing and the speed of relative movement between the rotation of the platen and the carrier affects the finishing quality.

The polishing conditions are not particularly limited. To efficiently perform polishing, the rotational speed of each of the platen and the substrate to be polished is preferably as low as 300 rpm or less. The pressure applied to the substrate to be polished in order to press the substrate against the polishing surface of the polishing pad is preferably 150 kPa or less, from the viewpoint of preventing generation of scratches after polishing. During polishing, it is preferable that the slurry is continuously or discontinuously supplied to the polishing pad such that the slurry is evenly delivered onto the polishing surface.

Then, after fully washing the substrate to be polished that has undergone polishing, the substrate to be polished is dried by removing water droplets attached thereto by using a spin drier or the like. In this manner, the surface to be polished becomes a smooth surface.

Such CMP according to the present embodiment can be preferably used for polishing performed during the manufacturing process of various semiconductor devices, micro electro mechanical systems (MEMS), and the like. Examples of the object to be polished include semiconductor substrates such as silicon, silicon carbide, gallium nitride, gallium arsenic, zinc oxide, sapphire, germanium, and diamond; wiring materials, including, for example, an insulating film such as a silicon oxide film, a silicon nitride film, or a low-k film formed on a wiring board having predetermined wiring, and copper, aluminum, and tungsten; glass, crystal, an optical substrate, and a hard disk. In particular, the polishing pad according to the present embodiment is preferably used for polishing insulating films and wiring materials formed on semiconductor substrates.

### EXAMPLES

Hereinafter, the present invention will be described more specifically by way of examples. It should be appreciated that the scope of the invention is by no means limited to the examples.

First, hygroscopic polymers used in the examples will be collectively shown below.

### <Hygroscopic Polymer>

Polyethylene oxide having a weight-average molecular weight of 30,000 (PEO 30,000); moisture absorption rate 0.7% (in the range of 0.1 to 3.0%)
Polyethylene oxide having a weight-average molecular weight of 100,000 (PEO 100,000); moisture absorption rate 0.5%
Polyethylene oxide having a weight-average molecular weight of 1,000,000 (PEO 1,000,000); moisture absorption rate 1.6% (in the range of 0.1 to 3.0%)
Polyethylene oxide having a weight-average molecular weight of 7,000,000 (PEO 7,000,000); moisture absorption rate 2.5% (in the range of 0.1 to 3.0%)
Polyethylene oxide-propylene oxide block copolymer having a weight-average molecular weight of 100,000 (PEO-PPO 100,000); moisture absorption rate 0.7% (in the range of 0.1 to 3.0%)
Polyethylene oxide-propylene oxide block copolymer having a weight-average molecular weight of 1,000,000 (PEO-PPO 1,000,000); moisture absorption rate 1.3% (in the range of 0.1 to 3.0%)
Polyethylene oxide-propylene oxide block copolymer having a weight-average molecular weight of 7,000,000 (PEO-PPO 7,000,000); moisture absorption rate 2.1% (in the range of 0.1 to 3.0%)
Polyester-based thermoplastic elastomer (TPEE); moisture absorption rate 1.2% (in the range of 0.1 to 3.0%)

### <Acrylonitrile-Styrene Copolymer>

Acrylonitrile-styrene copolymer; moisture absorption rate 0.08%

Here, the moisture absorption rates of the polymers were measured in the following manner.

On a plate made of glass, 5.0 g of particles of each of the polymers were thinly spread, and then allowed to stand in a hot-air dryer at 50° C. for 48 hours to be dried. Thereafter, the particles were allowed to stand under constant temperature and humidity conditions of 23° C. and 50% RH for 24 hours. Then, a weight (W1) immediately before the treatment under the constant temperature and humidity conditions of 23° C. and 50% RH, and a weight (W2) after the treatment under the constant temperature and humidity conditions of 23° C. and 50% RH were measured, and the moisture absorption rate was determined from the following mathematical expression:

Moisture absorption rate (%)={(W2−W1)/W1}×100

Production examples of the polyurethanes used in the present examples are shown below.

### Production Example 1

Poly(ethylene glycol) [abbreviation: PEG] having a number-average molecular weight of 600, 1,4-butanediol [abbreviation: BD], 1,5-pentanediol [abbreviation: MPD], and 4,4′-diphenylmethane diisocyanate [abbreviation: MDI] were mixed in a mass ratio of PEG:BD:MPD:MDI of 15.2:14.2:8.0:62.6, to prepare a blend.

Then, the blend was continuously supplied to a coaxially rotating twin-screw extruder using a metering pump, and the molten blend was continuously extruded in the form of strands into water, and subsequently finely cut into pellets using a pelletizer. A non-alicyclic thermoplastic polyurethane I was produced by subjecting the polyurethane raw material to continuous melt-polymerization in this manner. The non-alicyclic thermoplastic polyurethane I includes, in the total amount of the organic diisocyanate unit, 100 mol % of MDI serving as a non-alicyclic diisocyanate unit. The weight-average molecular weight of the non-alicyclic thermoplastic polyurethane I was 120,000. Then, the obtained pellets were dried through dehumidification at 70° C. for 20 hours.

### Production Example 2

Poly(tetramethylene glycol) [abbreviation: PTMG] having a number-average molecular weight of 850, 1,4-butanediol [abbreviation: BD], 1,5-pentanediol [abbreviation: MPD], and 4,4′-diphenylmethane diisocyanate [abbreviation: MDI] were mixed in a mass ratio of PTMG:BD:MPD:MDI of 10.2:15.7:8.8:65.3, to prepare a blend. Except for using this blend, a non-alicyclic thermoplastic polyurethane II was produced by subjecting the polyurethane raw material to continuous melt-polymerization in the same manner as in Production Example 1. The non-alicyclic thermoplastic polyurethane II includes, in the total amount of the organic diisocyanate unit, 100 mol % of MDI serving as a non-alicyclic diisocyanate unit. The weight-average molecular weight of the non-alicyclic thermoplastic polyurethane II was 120,000. Then, the obtained pellets were dried through dehumidification at 70° C. for 20 hours.

### Production Example 3

Poly(ethylene glycol) [abbreviation: PEG] having a number-average molecular weight of 600, 1,4-butanediol [abbreviation: BD], 1,5-pentanediol [abbreviation: MPD], and hexamethylene diisocyanate [abbreviation: HDI] were mixed in a mass ratio of PEG:BD:MPD:HDI of 11.6:16.5:9.3:62.6, to prepare a blend. Except for using this blend, a non-alicyclic thermoplastic polyurethane III was produced by subjecting the polyurethane raw material to continuous melt-polymerization in the same manner as in Production Example 1. The non-alicyclic thermoplastic polyurethane III includes, in the total amount of the organic diisocyanate unit, 100 mol % of HDI serving as a non-alicyclic diisocyanate unit. The weight-average molecular weight of the non-alicyclic thermoplastic polyurethane III was 120,000. Then, the obtained pellets were dried through dehumidification at 70° C. for 20 hours.

### Production Example 4

Poly(ethylene glycol) [abbreviation: PEG] having a number-average molecular weight of 600, 1,4-butanediol [abbreviation: BD], 1,5-pentanediol [abbreviation: MPD], and isophorone diisocyanate [abbreviation: IPDI] were mixed in a mass ratio of PEG:BD:MPD:IPDI of 15.2:14.2:8.0:62.6, to prepare a blend. Except for using this blend, an alicyclic thermoplastic polyurethane IV was produced by subjecting the polyurethane raw material to continuous melt-polymerization in the same manner as in Production Example 1. The alicyclic thermoplastic polyurethane IV includes, in the total amount of the organic diisocyanate unit, 100 mol % of IPDI serving as an alicyclic diisocyanate unit. The weight-average molecular weight of the alicyclic thermoplastic polyurethane IV was 120,000. Then, the obtained pellets were dried through dehumidification at 70° C. for 20 hours.

### Production Example 5

Poly(ethylene glycol) [abbreviation: PEG] having a number-average molecular weight of 600, 1,4-butanediol [abbreviation: BD], 1,5-pentanediol [abbreviation: MPD], and cyclohexanemethyl isocyanate [abbreviation: CHI] were mixed in a mass ratio of PEG:BD:MPD:CHI of 15.2:14.2:8.0:62.6, to prepare a blend. Except for using this blend, an alicyclic thermoplastic polyurethane V was produced by subjecting the polyurethane raw material to continuous melt-polymerization in the same manner as in Production Example 1. The alicyclic thermoplastic polyurethane V includes, in the total amount of the organic diisocyanate unit, 100 mol % of CHI serving as an alicyclic diisocyanate unit. The weight-average molecular weight of the alicyclic thermoplastic polyurethane V was 120,000. Then, the obtained pellets were dried through dehumidification at 70° C. for 20 hours. Here, 1,3-Bis(isocyanatomethyl)cyclohexane (Takenate 600 (registered trademark) from Mitsui Chemicals, Inc.) was used as the cyclohexanemethyl isocyanate.

### Example 1

The non-alicyclic thermoplastic polyurethane I was charged into a small-sized kneader, and melt-kneaded at a temperature of 240° C. and a screw speed of 100 rpm for a kneading time of 1 minute. Then, PEO 100,000 was added into the small-sized kneader in a mass ratio of non-alicyclic thermoplastic polyurethane I:PEO 100,000=99.5:0.5, and the whole was further melt-kneaded at a temperature of 240° C. and a screw speed of 60 rpm for a kneading time of 2 minutes. The whole was further melt-kneaded at a temperature of 240° C. and a screw speed of 100 rpm for a kneading time of 4 minutes.

Then, the obtained molten mixture was allowed to stand in a vacuum drier at 70° C. for 16 hours or more to be dried. Then, the dried molten mixture was sandwiched between metal plates, which were then held in a hot press molding machine, and the molten mixture was allowed to melt at a heating temperature of 230° C. for 2 minutes. Thereafter, the molten mixture was pressurized at a gauge pressure of 40 kg/cm², and then allowed to stand for 1 minute. Then, the whole was cooled at room temperature, followed by removing a 2.0-mm-thick molded body held in the hot press molding machine and sandwiched between the metal plates.

Then, the obtained 2.0-mm-thick molded body was heat-treated at 110° C. for 3 hours, and subsequently subjected to cutting, to cut out a rectangular test piece measuring 30 mm×50 mm. Then, the test piece was subjected to cutting, to form concentric striped grooves (width 1.0 mm, depth 1.0 mm, groove interval 6.5 mm). Then, a recess for housing the test piece was formed in a 2.0-mm-thick circular molded body of the non-alicyclic thermoplastic polyurethane I, and the test piece are fitted to the recess, to obtain an unfoamed molded body of a polishing layer for evaluation. Then, the polishing layer was evaluated in the following manner.

### [Durometer D Hardness of Molded Body]

Using a type-D durometer compliant with JIS K 7215 (HARDNESS-TESTER manufactured by SHIMADZU CORPORATION), the type-D durometer hardness of the 2.0-mm-thick molded body was measured for a load holding time of 5 seconds.

### [Vickers Hardness of Molded Body]

Using a Vickers hardness meter (HARDNESS-TESTER MVK-E2 manufactured by Akashi Seisakusho, Ltd.) compliant with JIS Z2244, the Vickers hardness of the 2.0-mm-thick molded body was measured.

[Dry State-Breaking Elongation, and Saturated Swollen State-Breaking Elongation when Swollen to Saturation with Water at 50° C., of Molded Body]

In place of the 2.0-mm-thick molded body, a 0.3-mm-thick molded body was produced. Then, a No. 2 test piece (JIS K 7113) was punched out from the 0.3-mm-thick molded body. Then, the No. 2 test piece was conditioned at a humidity of 48 RH % and 23° C. for 24 hours. Then, using a precision universal tester (Autograph AG5000 manufactured by SHIMADZU CORPORATION), tensile testing was performed on the conditioned No. 2 test piece, to measure the breaking elongation. The tensile testing was performed under conditions of an interchuck distance of 40 mm, a tensile speed of 500 mm/min, a humidity of 48 RH %, and 23° C. The breaking elongations of five samples of the No. 2 test piece were measured, and the average value thereof was calculated as a dry state-breaking elongation S2(%). Meanwhile, a No. 2 test piece was immersed in warm water at 50° C. for 2 days, to allow the test piece to be swollen to saturation with water at 50° C. Then, the breaking elongation of the No. 2 test piece swollen to saturation was also measured in the same conditions, to obtain a saturated swollen state-breaking elongation S1 when swollen to saturation with water at 50° C.

[Storage Modulus E′ of Molded Body when Swollen to Saturation with Water at 50° C.]

Instead of the 2.0-mm-thick molded body, a 0.3-mm-thick molded body was produced. Then, the 0.3-mm-thick molded body was heat-treated at 110° C. for 3 hours, and subsequently punched out into a test piece using a rectangular die measuring 30 mm×5 mm, to punch out a test piece measuring 30 mm×5 mm for storage modulus evaluation. Then, the test piece was immersed in warm water at 50° C. for 2 days, to allow the test piece for storage modulus evaluation to be swollen to saturation with water at 50° C. Then, using a dynamic viscoelasticity measurement device [DVE Rheospectra (trade name, manufactured by Rheology Co., Ltd.)], the dynamic viscoelastic modulus at 70° C. was measured in the measurement range of −100 to 180° C. at a frequency of 11.0 Hz, to determine a storage modulus E′ of the molded body when swollen to saturation with water at 50° C. The storage moduli E′ of two samples of the test piece were measured, and the average value was calculated as a storage modulus E′ (GPa).

[Light Transmittance of Molded Body when Swollen to Saturation with Water at 50° C.]

A 0.5-mm-thick molded body was produced in place of the 2.0-mm-thick molded body. Then, the 0.5-mm-thick molded body was heat-treated at 110° C. for 3 hours, and subsequently subjected to cutting, to cut out a rectangular piece measuring 10 mm×40 mm. Then, the test piece was immersed in warm water at 50° C. for 2 days, to allow the test piece to be swollen to saturation with water at 50° C., and then, water droplets on the surface were wiped off. Then, using an ultraviolet-visible spectrophotometer (“UV-2450” manufactured by SHIMADZU CORPORATION), the light transmittance for a wavelength of 550 nm of the test piece of the molded body was measured under the following conditions.
Light source: laser wavelength (550 nm)
WI lamp: 50 W
Distance between detection head and output head: 10 cm
Measurement position of test piece: intermediate position between detection head and output head

### [Dressing Performance (Arithmetic Surface Roughness Ra)]

The polishing layer for evaluation was set on a platen of a CMP apparatus (FREX 300 manufactured by EBARA CORPORATION). Then, using a diamond dresser having a diamond grit number of #100 (Asahi Diamond Industrial Co., Ltd.), the surface of the polishing layer was dressed for 10 minutes at a dresser rotation rate of 100 rpm, a table rotation rate of 70 rpm, and a dresser load of 40 N, while pouring a slurry onto the surface at a rate of 150 mL/min. Then, the arithmetic surface roughness Ra of the dressed surface of the polishing layer was measured using a surface roughness tester (SJ-210 manufactured by Mitutoyo Corporation).

### [Evaluation of Polishing Characteristics]

The polishing layer for evaluation was set on a platen of a CMP apparatus (FREX 300 manufactured by EBARA CORPORATION). Then, using a diamond dresser having a diamond grit number of #100 (Asahi Diamond Industrial Co., Ltd.), a surface of a substrate to be polished was polished at a dresser rotation rate of 100 rpm, a table rotation rate of 70 rpm, and a dresser load of 40 N, while pouring a slurry (Klebosol (registered trademark) from DuPont) onto the surface at a rate of 200 mL/min. As the substrate to be polished, a “SEMATECH 764 (SKW Associates Ltd.)” obtained by laminating a TEOS film (tetraethoxysilane film) having a thickness of 3000 nm onto a silicon substrate. CMP was performed under the above-described conditions, and the difference between protrusions and recesses (hereinafter also referred to as a residual level difference) in portions in which continuous patterns each having a width of 250 μm (50% density) were formed, was measured as an indicator of the planarization performance using a precision level difference meter (Dektak XTL manufactured by Bruker Corporation). Note that when the residual level difference was 40 nm or less, or even 35 nm or less, or particularly 33 nm or less, it was determined that the polishing layer had high planarization performance. Similarly, the polishing rate was evaluated by measuring the polishing time required until the thickness of the residual film on the protrusions became less than 50 nm. Note that when the polishing time was 150 sec or less, even 145 sec or less, it was determined that the polishing layer had a high polishing rate.

Then, using a wafer defect inspection device (SP-3 manufactured by KLA Tencor Corporation), the number of scratches larger than 0.21 μm on the entire surface of the polished substrate to be polished was counted. Note that when the number of the scratches was less than 30, it was determined that the generation of scratches was suppressed.

The evaluation results are shown in Table 1 below.

TABLE 1

| | | | Example No. | | | | | | | | |
|---|---|---|---|---|---|---|---|---|---|---|---|
| | | | 1 | 2 | 3 | 4 | 5 | 6 | 7 | 8 | 9 |
| Polyurethane | Non-alicyclic | Type | I | I | I | I | II | II | I | I | I |
| composition | thermoplastic | Diisocyanate | MDI | MDI | MDI | MDI | MDI | MDI | MDI | MDI | MDI |
| | polyurethane | unit | | | | | | | | | |
| | | Parts by | 99.5 | 99 | 99 | 90 | 99 | 90 | 99 | 90 | 99 |
| | | mass | | | | | | | | | |
| | Alicyclic | Type | — | — | — | — | — | — | — | — | — |
| | thermoplastic | Diisocyanate | — | — | — | — | — | — | — | — | — |
| | polyurethane | unit | | | | | | | | | |
| | | Parts by | — | — | — | — | — | — | — | — | — |
| | | mass | | | | | | | | | |
| | Hygroscopic | Type | PEO | PEO | PEO | PEO | PEO | PEO | PEO | PEO | PEO |
| | polymer | | 100,000 | 30,000 | 100,000 | 100,000 | 100,000 | 100,000 | 100,000 | 1,000,000 | 7,000,000 |
| | | Parts by | 0.5 | 1 | 1 | 10 | 1 | 10 | 1 | 10 | 1 |
| | | mass | | | | | | | | | |

| | | | | | | | | | | |
|---|---|---|---|---|---|---|---|---|---|---|
| Molded | Durometer D hardness | 82 | 82 | 81 | 76 | 86 | 81 | 81 | 76 | 83 |
| body | Vickers hardness | 56 | 59 | 54 | 26 | 65 | 54 | 53 | 28 | 57 |
| | Saturated swollen | 118 | 93 | 126 | 191 | 64 | 108 | 153 | 226 | 106 |
| | state-breaking | | | | | | | | | |
| | elongation S1 (%) | | | | | | | | | |
| | Dry state-breaking | 4 | 4 | 3 | 6 | 3 | 5 | 6 | 6 | 4 |
| | elongation S2 (%) | | | | | | | | | |
| | S1/S2 | 29.5 | 23.3 | 42.0 | 31.8 | 21.3 | 21.6 | 25.5 | 37.7 | 26.5 |
| | Light transmittance | 72 | 77 | 75 | 74 | 80 | 71 | 68 | 65 | 69 |
| | for 550 nm when | | | | | | | | | |
| | swollen to | | | | | | | | | |
| | saturation with | | | | | | | | | |
| | water at 50° C. (%) | | | | | | | | | |
| | Storage modulus E′ | 0.5 | 0.3 | 0.3 | 0.2 | 0.3 | 0.3 | 0.4 | 0.4 | 0.6 |
| | when swollen to | | | | | | | | | |
| | saturation with | | | | | | | | | |
| | water at 50° C. [GPa] | | | | | | | | | |
| Evaluation | Surface roughness Ra | 6.3 | 5 | 6.2 | 7.8 | 6.7 | 4.9 | 5.2 | 5.1 | 4.5 |
| results | (μm) | | | | | | | | | |
| | Residual level | 25 | 33 | 20 | 28 | 27 | 32 | 22 | 31 | 11 |
| | difference (nm) | | | | | | | | | |
| | Polishing time (sec) | 147 | 130 | 139 | 157 | 135 | 148 | 138 | 152 | 135 |
| | Number of scratches | 24 | 20 | 14 | 21 | 24 | 19 | 20 | 28 | 18 |
| | (pcs) | | | | | | | | | |

| | | | Example No. | | | | | |
|---|---|---|---|---|---|---|---|---|
| | | | 10 | 11 | 12 | 13 | 14 | 15 |
| Polyurethane | Non-alicyclic | Type | I | I | I | III | I | I |
| composition | thermoplastic | Diisocyanate | MDI | MDI | MDI | HDI | MDI | MDI |
| | polyurethane | unit | | | | | | |
| | | Parts by | 99 | 99 | 99 | 99 | 95 | 99 |
| | | mass | | | | | | |
| | Alicyclic | Type | — | — | — | — | IV | — |
| | thermoplastic | Diisocyanate | — | — | — | — | IPDI | — |
| | polyurethane | unit | | | | | | |
| | | Parts by | — | — | — | — | 4 | — |
| | | mass | | | | | | |
| | Hygroscopic | Type | PEO-PPO | PEO-PPO | PEO-PPO | PEO-PPO | PEO-PPO | TPEE |
| | polymer | | 100,000 | 1,000,000 | 7,000,000 | 100,000 | 1,000,000 | 100,000 |
| | | Parts by | 1 | 1 | 1 | 1 | 1 | 1 |
| | | mass | | | | | | |

| | | | | | | | |
|---|---|---|---|---|---|---|---|
| Molded | Durometer D hardness | 79 | 80 | 83 | 82 | 83 | 82 |
| body | Vickers hardness | 47 | 52 | 56 | 52 | 57 | 57 |
| | Saturated swollen | 118 | 105 | 112 | 170 | 69 | 110 |
| | state-breaking | | | | | | |
| | elongation S1 (%) | | | | | | |
| | Dry state-breaking | 4 | 3 | 5 | 8 | 5 | 4 |
| | elongation S2 (%) | | | | | | |
| | S1/S2 | 29.5 | 35.0 | 22.4 | 21.3 | 13.8 | 27.5 |
| | Light transmittance | 79 | 71 | 72 | 77 | 52 | 70 |
| | for 550 nm when | | | | | | |
| | swollen to | | | | | | |
| | saturation with | | | | | | |
| | water at 50° C. (%) | | | | | | |
| | Storage modulus E′ | 0.7 | 0.4 | 0.5 | 0.4 | 0.9 | 0.4 |
| | when swollen to | | | | | | |
| | saturation with | | | | | | |
| | water at 50° C. [GPa] | | | | | | |
| Evaluation | Surface roughness Ra | 5.7 | 6.3 | 6.5 | 5.8 | 4.1 | 5.1 |
| results | (μm) | | | | | | |
| | Residual level | 18 | 23 | 17 | 24 | 43 | 30 |
| | difference (nm) | | | | | | |
| | Polishing time (sec) | 136 | 133 | 137 | 150 | 184 | 150 |
| | Number of scratches | 15 | 22 | 18 | 19 | 33 | 22 |
| | (pcs) | | | | | | |

### Examples 2 to 15, Comparative Examples 1 to 6

The characteristics of the molded bodies or the polishing layers were evaluated in the same manner as in Example 1, except that the types of the polyurethane composition were changed to the compositions shown in Table 1 or 2. The results are shown in Table 1 or 2 below.

TABLE 2

| | | | Comparative Example No. | | | | | |
|---|---|---|---|---|---|---|---|---|
| | | | Com. Ex. | Com. Ex. | Com. Ex. | Com. Ex. | Com. Ex. | Com. Ex. |
| | | | 1 | 2 | 3 | 4 | 5 | 6 |
| Polyurethane | Non-alicyclic | Type | I | II | I | I | I | I |
| composition | thermoplastic | Diisocyanate | MDI | MDI | MDI | MDI | MDI | MDI |
| | polyurethane | unit | | | | | | |
| | | Parts by | 100 | 100 | 85 | 85 | 80 | 99 |
| | | mass | | | | | | |
| | Alicyclic | Type | — | — | IV | V | — | — |
| | thermoplastic | Diisocyanate | — | — | IPDI | CHI | — | — |
| | polyurethane | unit | | | | | | |
| | | Parts by | — | — | 14 | 1.4 | — | — |
| | | mass | | | | | | |
| | Hygroscopic polymer | Type | — | — | PEO-PPO | PEO-PPO | PEO | — |
| | | | | | 1,000,000 | 1,000,000 | 100,000 | |
| | | Parts by | — | — | 1 | 1 | 20 | — |
| | | mass | | | | | | |
| | Acrylonitrile- | Parts by | — | — | — | — | — | 1 |
| | styrene copolymer | mass | | | | | | |

| | | | | | | | |
|---|---|---|---|---|---|---|---|
| Molded body | Durometer D hardness | 83 | 85 | 82 | 84 | 70 | 80 |
| | Vickers hardness | 54 | 65 | 56 | 60 | 18 | 52 |
| | Saturated swollen state-breaking | 101 | 10 | 47 | 43 | 230 | 60 |
| | elongation S1 (%) | | | | | | |
| | Dry state-breaking elongation | 7 | 3 | 4 | 4 | 5 | 4 |
| | S2(%) | | | | | | |
| | S1/S2 | 14.4 | 3.3 | 11.8 | 10.8 | 46.0 | 15.0 |
| | Light transmittance for 550 nm | 76 | 75 | 27 | 34 | 60 | 32 |
| | when swollen to saturation with | | | | | | |
| | water at 50° C. (%) | | | | | | |
| | Storage modulus at 50° C. [GPa] | 0.8 | 0.9 | 1.1 | 1.0 | 0.09 | 0.90 |
| Evaluation | Surface roughness Ra (μm) | 3.2 | 3.5 | 3.8 | 3.3 | 3.0 | 3.3 |
| results | Residual level difference (nm) | 36 | 35 | 40 | 37 | 68 | 38 |
| | Polishing time (sec) | 152 | 149 | 178 | 171 | 175 | 150 |
| | Number of scratches (pos) | 18 | 25 | 32 | 36 | 11 | 20 |

Referring to the tables, all of the polishing pads obtained in Examples 1 to 15 according to the present invention had a large surface roughness Ra, and exhibited excellent dressing performance. These polishing pads also had a small residual level difference, and also exhibited excellent planarization performance. Also, the polishing pads required a shorter polishing time, and achieved a high polishing rate. Furthermore, the polishing pads had less generation of scratches. In this manner, the polishing pads according to the present invention had a high polishing rate, high planarization performance, scratch resistance, and excellent dressing performance at the same time. On the other hand, the polishing pads obtained in Comparative Examples 1 and 2, which contained no hygroscopic polymer, had a significantly low surface roughness. The polishing pads obtained in Comparative Examples 3 to 5, in which the ratio of the thermoplastic polyurethane including the non-alicyclic diisocyanate unit was less than 90 mass %, also had a significantly low surface roughness. The polishing pad obtained in Comparative Example 5, which contained the hygroscopic polymer in an amount greater than 10 mass %, namely 20 mass %, had a large residual level difference, and exhibited poor planarization performance. The polishing pad obtained in Comparative Example 6, which contained 1 mass % of the acrylonitrile-styrene copolymer having a moisture absorption rate of 0.08%, in place of the hygroscopic polymer, also had a low surface roughness and a large residual level difference.

### REFERENCE SIGNS LIST

1 Platen
2 Slurry supply nozzle
3 Carrier
4 Dresser
5 Substrate to be polished
6 Slurry
10 Polishing pad
20 CMP apparatus

1: A polishing pad comprising a polishing layer that is a molded body of a polyurethane composition,
wherein the polyurethane composition contains 90 to 99.9 mass % of a thermoplastic polyurethane including a non-alicyclic diisocyanate unit as an organic diisocyanate unit, and 0.1 to 10 mass % of a hygroscopic polymer having a moisture absorption rate of 0.1% or more, and
the molded body has a D hardness of 75 to 90, as measured with a type-D durometer compliant with JIS K 7215 for a load holding time of 5 seconds.

2: The polishing pad according to claim 1, wherein the thermoplastic polyurethane includes, in a total amount of the organic diisocyanate unit, 90 to 100 mol % of 4,4′-diphenylmethane diisocyanate unit serving as the non-alicyclic diisocyanate unit.

3: The polishing pad according to claim 1, wherein the polyurethane composition contains 99 to 99.9 mass % of the thermoplastic polyurethane, and 0.1 to 1 mass % of the hygroscopic polymer.

4: The polishing pad according to claim 1, wherein the hygroscopic polymer includes at least one selected from the group consisting of a polyethylene oxide (PEO), a polypropylene oxide (PPO), a PEO-PPO copolymer, a PEO-PPO block copolymer, and a polyester-based thermoplastic elastomer (TPEE).

5: The polishing pad according to claim 1, wherein the molded body has a saturated swollen state-breaking elongation of 50 to 250% when swollen to saturation with water at 50° C.

6: The polishing pad according to claim 5, wherein the molded body has a dry state-breaking elongation of 0.1 to 10% at a humidity of 48 RH % and 23° C.

7: The polishing pad according to claim 6, wherein the molded body has a ratio S₁/S₂ of 20 to 50, where S₁ represents the saturated swollen state-breaking elongation and S₂ represents the dry state-breaking elongation.

8: The polishing pad according to claim 1, wherein the molded body, in a form of a sheet having a thickness of 0.5 mm, has a laser light transmittance of 60% or more for 550-nm wavelength when swollen to saturation with water at 50° C.

9: The polishing pad according to claim 1, wherein the molded body has a Vickers hardness of 21 or more.

10: The polishing pad according to claim 1, wherein the molded body has a storage modulus of 0.1 to 1.0 GPa when swollen to saturation with water at 50° C.

11: The polishing pad according to claim 1, wherein the molded body is an unfoamed molded body.

12: The polishing pad according to claim 1, wherein a content ratio of the non-alicyclic diisocyanate unit contained in a total amount of the organic diisocyanate units contained in the thermoplastic polyurethane is 90 to 100 mol %.

13: The polishing pad according to claim 4, wherein a content ratio of the non-alicyclic diisocyanate unit contained in a total amount of the organic diisocyanate units contained in the thermoplastic polyurethane is 90 to 100 mol %.

14: The polishing pad according to claim 1, wherein a content ratio of the non-alicyclic diisocyanate unit contained in a total amount of the organic diisocyanate units contained in the thermoplastic polyurethane is 95 to 100 mol %.

15: The polishing pad according to claim 4, wherein a content ratio of the non-alicyclic diisocyanate unit contained in a total amount of the organic diisocyanate units contained in the thermoplastic polyurethane is 95 to 100 mol %.

16: The polishing pad according to claim 1, wherein a content ratio of the non-alicyclic diisocyanate unit contained in a total amount of the organic diisocyanate units contained in the thermoplastic polyurethane is 100 mol %.

17: The polishing pad according to claim 4, wherein a content ratio of the non-alicyclic diisocyanate unit contained in a total amount of the organic diisocyanate units contained in the thermoplastic polyurethane is 100 mol %.

18: The polishing pad according to claim 1, wherein the hygroscopic polymer has a weight-average molecular weight of 5,000 to 10,000,000.
